(19) United States
(12) Patent Application Publication
(10) Pub. No.: US 2025/0265393 A1
(43) Pub. Date: Aug. 21, 2025

(54) INFORMATION PROCESSING APPARATUS, INFORMATION PROCESSING METHOD, AND PROGRAM

(71) Applicant: NEC Corporation, Tokyo (JP)

(72) Inventor: Joe BRINTON, Tokyo (JP)

(73) Assignee: NEC Corporation, Tokyo (JP)

(21) Appl. No.: 19/050,337

(22) Filed: Feb. 11, 2025

(30) Foreign Application Priority Data
Feb. 21, 2024 (JP) 2024-024466

(51) Int. Cl. G06F 30/27; G06F 30/18

(52) U.S. Cl. CPC G06F 30/27; G06F 30/18

(57) ABSTRACT

An information processing apparatus of the present disclosure includes: a configuration collecting unit that collects system configuration information included by design path information; a feature value generating unit that generates a feature value of an element in the system configuration information included by the design path information; a distributed representation learning unit that acquires, by machine learning, a parameter for calculating a distributed representation of the element using graph structure information representing a relation between the elements and the feature value of the element; and a converting unit that generates design path information with distributed representation by calculating the distributed representation of the element in the system configuration information included by the design path information using the parameter and then assigning the distributed representation to the design path information.

### INCORPORATION BY REFERENCE

This application is based upon and claims the benefit of priority from Japanese patent application No. 2024-024466, filed on Feb. 21, 2024, the disclosure of which is incorporated herein in its entirety by reference.

### TECHNICAL FIELD

The present disclosure relates to an information processing apparatus, an information processing method, and a program.

### BACKGROUND ART

When designing an ICT (Information and Communication Technology) system, first, in requirements definition, the designer creates system requirements, which are information summarizing customer's requirements. At this time, system requirements generally include abstract information and often do not represent a deployable system configuration as they are. Therefore, the designer concretizes stepwise the abstract information included in the system requirements and designs a deployable system configuration in which all the information are concrete finally.

Since this series of actions requires expertise in elements included in a system configuration and the relation between the elements, man-hours related to design and necessary human costs increase as a system becomes sophisticated.

As a method for solving the above problem, an automated system design technique has been proposed. The automated system design technique is a technique of automatically deriving a system configuration including only concrete information based on system requirements including abstract information.

As a related technique, Patent Literature 1 discloses a system configuration derivation apparatus that can concretize stepwise abstract parts included in system requirements based on the requirements and derive a deployable and concrete ICT system configuration.

The system configuration derivation apparatus of Patent Literature 1 learns a method for calculating a score representing the degree of adequacy of a concretization rule that is a rule for rewriting in more detail part of configuration requirements representing requirements concerning an ICT system.

When an abstract system requirement is entered, the apparatus having thus learned can select adequate concretization rules and design a concrete system configuration speedily and automatically.
Patent Literature 1: Japanese Patent No. 6989014
Non-Patent Literature 1: Hamilton, W. L., Ying, Z., & Leskovec, J. (2017). Inductive Representation Learning on Large Graphs. Neural Information Processing Systems.
Non-patent Literature 2: Velickovic, P., Cucurull, G., Casanova, A., Romero, A., Lio′, P., & Bengio, Y. (2017). Graph Attention Networks. ArXiv, abs/1710.10903.

However, the technique described in the Patent Literature 1 above does not guarantee accuracy in precision of evaluation by the apparatus for a new element (unlearned element) that does not exist in the past learning process. Therefore, when designing a system using an unlearned element, the apparatus cannot utilize a learning experience concerning a previously learned element for evaluation of the quality of the unlearned element, and cannot perform highly precise system design.

Therefore, the technique described in Patent Literature 1 has a problem that the apparatus needs relearning when it is desired to design a system using a new element, which requires time cost.

### SUMMARY OF THE INVENTION

Accordingly, an object of the present disclosure is to solve the abovementioned problem that time cost is required for system design.

An information processing apparatus as an aspect of the present disclosure includes: a configuration collecting unit that collects system configuration information included by design path information representing a process of designing the system configuration information, the system configuration information representing a system configuration including a combination of elements designed by converting an abstract element into a concrete element using a preset concretization rule; a feature value generating unit that generates a feature value of the element in the system configuration information included by the design path information; a distributed representation learning unit that acquires, by machine learning, a parameter for calculating a distributed representation of the element using graph structure information representing a relation between the elements in the system configuration information by a graph structure and the feature value of the element; and a converting unit that, for the design path information to be a target for learning by a learning model to be machine-learned so as to convert the abstract element into the concrete element using the concretization rule, generates design path information with distributed representation by calculating the distributed representation of the element in the system configuration information included by the design path information using the parameter and then assigning the distributed representation to the design path information.

Further, an information processing method as an aspect of the present disclosure is a method by an information processing apparatus, and the method includes: collecting system configuration information included by design path information representing a process of designing the system configuration information, the system configuration information representing a system configuration including a combination of elements designed by converting an abstract element into a concrete element using a preset concretization rule; generating a feature value of the element in the system configuration information included by the design path information; acquiring, by machine learning, a parameter for calculating a distributed representation of the element using graph structure information representing a relation between the elements in the system configuration information by a graph structure and the feature value of the element; and for the design path information to be a target for learning by a learning model to be machine-learned so as to convert the abstract element into the concrete element using the concretization rule, generating design path information with distributed representation by calculating the distributed representation of the element in the system configuration information included by the design path information using the parameter and then assigning the distributed representation to the design path information.

Further, a program as an aspect of the present disclosure includes instructions for causing an information processing apparatus to execute processes to: collect system configuration information included by design path information representing a process of designing the system configuration information, the system configuration information representing a system configuration including a combination of elements designed by converting an abstract element into a concrete element using a preset concretization rule; generate a feature value of the element in the system configuration information included by the design path information; acquire, by machine learning, a parameter for calculating a distributed representation of the element using graph structure information representing a relation between the elements in the system configuration information by a graph structure and the feature value of the element; and for the design path information to be a target for learning by a learning model to be machine-learned so as to convert the abstract element into the concrete element using the concretization rule, generate design path information with distributed representation by calculating the distributed representation of the element in the system configuration information included by the design path information using the parameter and then assigning the distributed representation to the design path information.

Configured as described above, the present disclosure can reduce time cost when performing system design.

### BRIEF DESCRIPTION OF DRAWINGS

FIG. 1 is a diagram for describing automatic design of a system in the present disclosure;

FIG. 2 is a diagram for describing automatic design of the system in the present disclosure;

FIG. 3 is a diagram for describing automatic design of the system in the present disclosure;

FIG. 4 is a diagram for describing automatic design of the system in the present disclosure;

FIG. 5 is a diagram for describing automatic design of the system in the present disclosure;

FIG. 6 is a block diagram showing the configuration of a graph conversion device in the present disclosure;

FIG. 7 is a block diagram showing the configuration of an automated system design learning apparatus in the present disclosure;

FIG. 8 is a flowchart showing an example of the operation of the graph conversion device in the present disclosure;

FIG. 9 is a flowchart showing an example of operation of collecting a system configuration in the present disclosure;

FIG. 10 is a flowchart showing an example of operation of generating design path information in the present disclosure;

FIG. 11 is a diagram showing an example of a search tree in the present disclosure;

FIG. 12 is a diagram showing an example of a data structure of search tree information in the present disclosure;

FIG. 13 is a diagram showing an example of a data structure of the design path information in a first example embodiment of the present disclosure;

FIG. 14 is a flowchart showing an example of operation of extracting information necessary for learning in the present disclosure;

FIG. 15 is a diagram showing an example of a data structure of type definition information, and a type and identification information corresponding to the type in the present disclosure;

FIG. 16 is a diagram showing an example of a type and a property defined by the type in the present disclosure;

FIG. 17 is a diagram showing an example of a property vector generated from type property information and a property list in the present disclosure;

FIG. 18 is a diagram showing information generated by combining type identification information and the property vector in the present disclosure;

FIG. 19 is a flowchart showing an example of operation of an automated system design learning apparatus in the present disclosure;

FIG. 20 is a flowchart showing an example of an overall flow of operation of reinforcement learning of the automated system design learning apparatus in the present disclosure;

FIG. 21 is a flowchart showing an example of operation in which the graph conversion device in the present disclosure generates design path information with distributed representation in the present disclosure;

FIG. 22 is a diagram showing an example of a data structure of the design path information with distributed representation in the present disclosure;

FIG. 23 is a flowchart showing an example of operation of setting a reward in the present disclosure;

FIG. 24 is a flowchart showing an example of operation of updating a reward in the present disclosure;

FIG. 25 is a flowchart showing an example of operation of generating learning data for learning by an automated system design learning apparatus in the present disclosure;

FIG. 26 is a flowchart showing an example of operation of learning of a learning model in the present disclosure;

FIG. 27 is a block diagram showing a hardware configuration of an information processing apparatus in the present disclosure; and

FIG. 28 is a block diagram showing a configuration of the information processing apparatus in the present disclosure.

### EXAMPLE EMBODIMENT

### First Example Embodiment

A first example embodiment of the present disclosure will be described with reference to the drawings. The drawings may be relevant to any of the example embodiments.

### [Overview of Existing Technique]

To begin with, the overview of automatic design of an ICT system in this example embodiment will be described. First, the premise is that the requirement and configuration of an ICT system can be expressed with a graph. A graph represents elements (components and the relation between the components) included in the configuration of an ICT system using nodes or edges. A node is an element that represents, for example, a device or an application. An edge is an element that represents a connection relation between two nodes.

As an example of an ICT system, a case of designing a face recognition system will be described. When designing a face recognition system, the designer first creates a system requirement for the face recognition system.

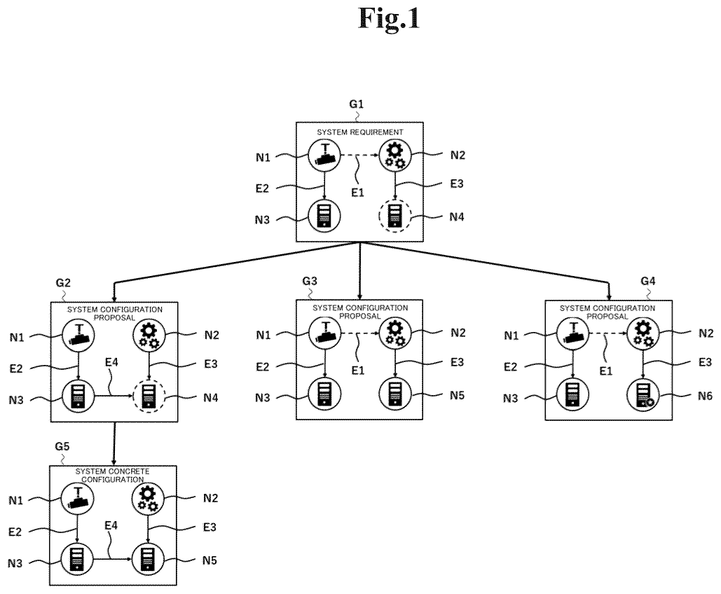

FIG. 1 is a diagram for describing automatic design of a face recognition system. A graph G1 in FIG. 1 is a graph showing the configuration of a system requirement R1 of the face recognition system. The graph G1 in FIG. 1 is shown using nodes N1, N2, N3 and N4 and edges E1, E2 and E3.

The node N1 represents a camera function as a concrete element (solid-line circle), the node N2 represents a face recognition function as a concrete element (solid-line circle), the node N3 represents a server computer function as a concrete element (solid-line circle), and the node N4 represents a server computer function as an abstract element (dashed circle). The edge E1 represents an HTTP communication function as an abstract element (dashed arrow), and the edges E2 and E3 represent join functions as concrete elements (solid-line arrows). The parts other than the graph G1 (system requirement) in FIG. 1 will be described later.

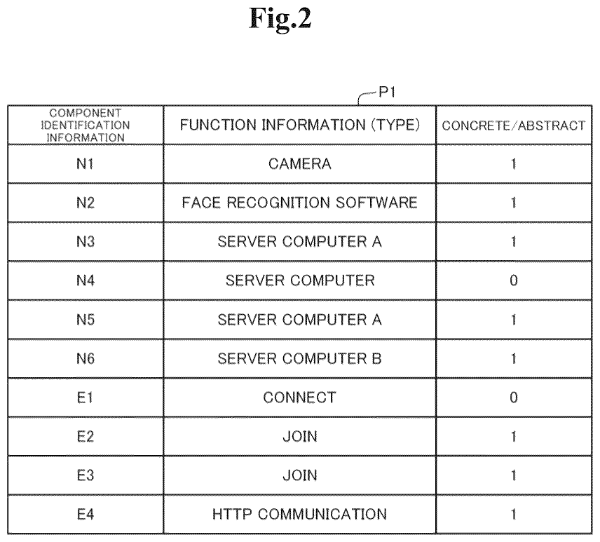

FIG. 2 is a diagram for explaining the data structure of component information that is information of the abovementioned elements. Component information P1 shown in FIG. 2 associates, for each of the component identification information for identifying nodes and edges, function information (also referred to as type) of the node or edge with information showing whether the node or edge is a concrete component (element) or an abstract component (element) (concrete (1)/abstract (0)).

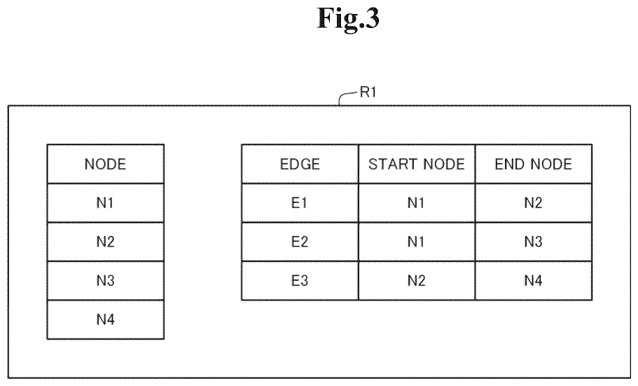

FIG. 3 is a diagram for explaining the data structure of a system requirement. The system requirement R1 of FIG. 3 is a system requirement corresponding to the graph G1 shown in FIG. 1. The system requirement R1 includes component identification information for identifying all the nodes included in the requirement. Then, the system requirement R1 is information including component identification information for identifying all the edges included in the requirement, component identification information for identifying the node equivalent to the start of the edge, and component identification information for identifying the node equivalent to the end of the edge.

In FIGS. 1 to 3 shown above, a graph, component information, and a system requirement are described using the graph G1, the component information P1, and the system requirement R1, but a graph, component information, and a system requirement are not limited to the graph G1, the component information P1, and the system requirement R1 shown in FIGS. 1 to 3.

Next, conversion from an abstract part into a concrete part in a graph in automated system design will be described. The example of FIG. 1 shows that graphs G2, G3 and G4 shown in FIG. 1 are derived by concretizing the graph G1 corresponding to the system requirement R1 based on a concretization rule to be described later. The graphs G2, G3 and G4 are system configuration proposals. A system configuration proposal includes an abstract component and is not a system requirement. As in the above, it is shown that a system concrete configuration G5 including no abstract element is derived by concretizing the system configuration proposal G2 using a concretization rule.

Further, although not illustrated in the example of FIG. 1, there may be a system configuration proposal derived by concretizing the graph G1 corresponding to the system requirement R1, other than the graphs G2, G3 and G4 of FIG. 1.

Next, a concretization rule will be described. A concretization rule is a rule for converting an abstract part included in a system requirement or a system configuration proposal into a concrete part. A concretization rule is information including detection information corresponding to an abstract part of a graph and conversion information corresponding to a concrete part of the graph.

Detection information and conversion information are graphs each including a node, an edge, or both, and one conversion information is associated with one detection information.

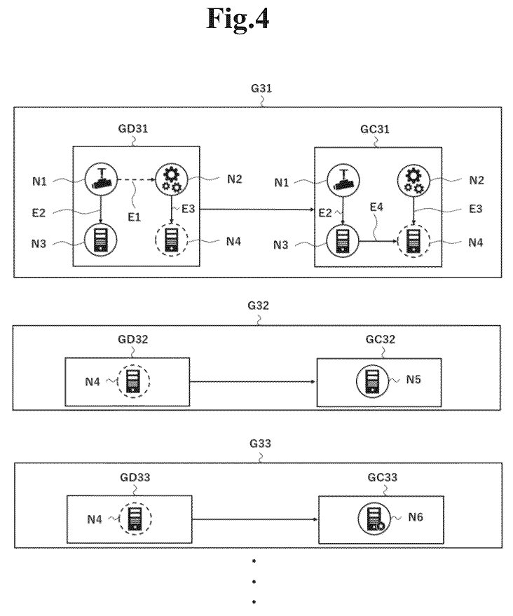

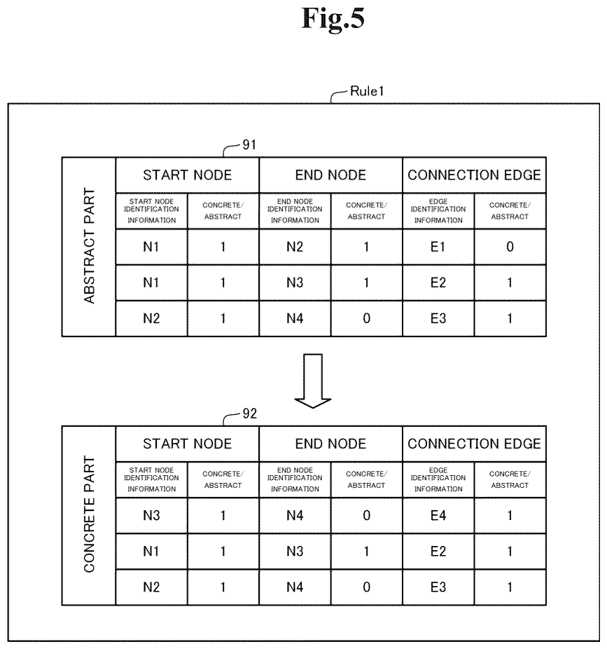

When the whole or part of a graph corresponding to a system requirement or a system configuration proposal matches the detection information included by a certain concretization rule, it is possible to concretize by applying the concretization rule and replacing the matching part with the conversion information. An example of the concretization rule will be described later with reference to FIG. 4. An example of the data structure of the concretization rule will be described later with reference to FIG. 5.

Although not illustrated in the example of FIG. 3, there are also system configuration proposals R2, R3 and R4 corresponding to the graphs G2, G3 and G4. Like the system requirement R1, each of the system configuration proposals R2, R3 and R4 is information including component identification information of all the nodes included in the configuration proposal, component identification information of all the edges, component identification information of the start nodes of the edges, and component identification information of the end nodes of the edges.

FIG. 4 is a diagram for explaining a concretization rule. FIG. 4 shows graphs G31, G32, G33, . . . , which are graphs representing a plurality of concretization rules.

The graph G31 is a graph representing a concretization rule Rule1 used for converting the graph G1 shown in FIG. 1 into the graph G2 shown in FIG. 1 (delete the edge E1, add an edge E4). A graph GD 31 included by the graph G31 is a graph representing detection information, and a graph GC31 is a graph representing conversion information. Since the graph GD 31 matches the graph G1 shown in FIG. 1, the concretization rule Rule1 can be applied. Then, by applying the concretization rule Rule1, the configuration of the graph G1 is replaced with the configuration of the graph GC31 and becomes the graph G2.

Further, the graph G32 is a graph representing a concretization rule Rule2 used for converting the graph G1 shown in FIG. 1 into the graph G3 shown in FIG. 1 (convert the node N4 into a node N5). The graph G33 is a graph representing a concretization rule Rule3 used for converting the graph G1 shown in FIG. 1 into the graph G4 shown in FIG. 1 (convert the node N4 into a node N6). As in the graph G31, a graph GD32 included by the graph G32 is a graph representing detection information, and a graph GC32 is a graph representing conversion information. Since the graph GD 32 matches part of the graph G1 shown in FIG. 1, the concretization rule Rule2 can be applied. Then, by applying the concretization rule Rule2, part of the graph G1 (i.e., the node N4) is replaced with the graph GC32 (i.e., the node N5), and the graph G1 is thereby converted into the graph G3. Moreover, as in the graph G31, a graph GD33 included by the graph G33 is a graph representing detection information, and a graph GC33 is a graph representing conversion information. Since the graph GD 33 matches part of the graph G1 shown in FIG. 1, the concretization rule Rule3 can be applied. Then, by applying the concretization rule Rule3, part of the graph G1 (i.e., the node N4) is replaced with the graph GC33 (i.e., the node N6), and the graph G1 is thereby converted into the graph G4.

FIG. 5 is a diagram for explaining the data structure of a concretization rule. The concretization rule Rule1 shown in FIG. 5 is the concretization rule corresponding to the graph G31. The concretization rule Rule1 includes detection information 91 used for detecting an abstract part and conversion information 92 for converting the abstract part detected using the detection information 91 into a concrete part. Although not illustrated, there are the concretization rules Rule2, Rule3, . . . like that shown in FIG. 5 corresponding to the graphs G32, G33, . . . for the graphs G32, G33, . . . .

For deriving the graphs G2, G3 and G4 from the graph G1 shown in FIG. 1, first, the system requirement R1 is compared with a plurality of detection information (correspond to abstract part in concretization rule), and detection information that matches an abstract part included in the system requirement R1 is detected.

Next, using the detected detection information corresponding to the abstract part, the abstract part detected from the system requirement R1 is converted into conversion information (concrete part in concretization rule). The conversion into the graph G2 is done by replacement with the conversion information 92 of the concretization rule Rule1 because the system requirement R1 matches the detection information 91 of the concretization rule Rule1. As a result, the edge E1 is deleted from the system requirement R1 and the edge E4 is added.

Although not illustrated here, the system configuration proposal R2 corresponding to the graph G2 is generated. The system configuration proposals R3 and R4 corresponding to the graphs G3 and G4, respectively, are also generated.

For each of the plurality of system configuration proposals generated in this manner (system configuration proposals R2, R3, and R4), an abstract part in the system configuration proposal is converted into a concrete part using the concretization rule. In a case where a system configuration proposal as an abstract system configuration is further generated as a result of converting the abstract part in the system configuration proposal into a concrete part using the concretization rule, the abovementioned concretization process is repeated. Then, when a system configuration proposal with no abstract part is generated, the concretization process is stopped (automatic design is ended).

Here, in the case of concretizing a system requirement and a system configuration proposal, a plurality of concretization rules are used, so that a system configuration proposal and a system concrete configuration to be derived vary in accordance with a selected concretization rule and the order of selection of concretization rules. That is to say, system configuration proposals and system concrete configurations with different configurations are derived in accordance with the types of concretization rules to be selected and the order thereof.

Further, when the number of concretization rules to be applied increases, the number of system configuration proposals and system concrete configurations to be generated becomes enormous. Furthermore, the plurality of different system concrete configurations may include a system concrete configuration that does not satisfy a system requirement. Therefore, as the number of concretization rules to be applied increases, it becomes difficult to efficiently derive a system concrete configuration.

Therefore, in order to efficiently derive a system concrete configuration, it is important to appropriately determine the quality of a concretization rule to be applied.

Then, a learning model is used to select a concretization rule to be applied. That is to say, evaluation is performed on system configuration proposals generated by execution of the concretization process, using a learning model acquired by machine learning, and a system configuration proposal with the highest evaluation value is selected from among the system configuration proposals. Thus, by repeating the concretization process using the learning model, the system concrete configuration can be derived efficiently.

In this example embodiment, a learning apparatus that generates a learning model for automatically designing a system as mentioned above, and a graph conversion device that solves the abovementioned problem by converting the learning data of the learning apparatus will be provided. In addition, the graph conversion device is a device that solves the problem described at the beginning of the present disclosure by converting the content of data to be learned by the learning apparatus.

Hereinafter, a graph conversion device in this example embodiment will be described. After that, an automated system design learning apparatus including the graph conversion device will be described. In the drawings described below, elements having the same functions, or the corresponding functions may be denoted by the same reference signs, and repeated description thereof may be omitted.

### [Configuration]

First, a configuration of the graph conversion device in the present disclosure will be presented, followed by a configuration of the automated system design learning apparatus that is a learning apparatus generating a learning model automatically designing a system and that includes the above graph conversion device as part of a function of the learning apparatus.

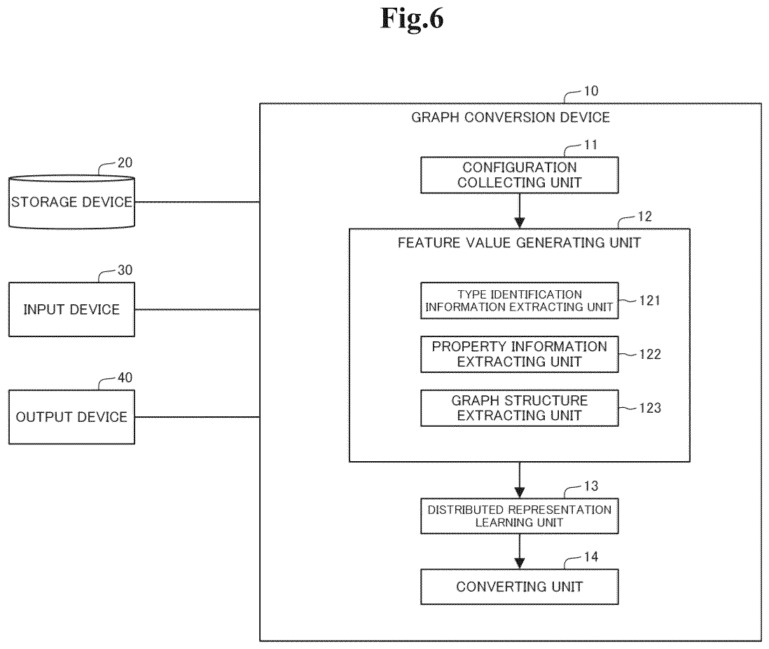

Using FIG. 6, a configuration of an information processing system having the graph conversion device 10 in the first example embodiment will be described. FIG. 6 is a diagram showing an example of the information processing system.

As shown in FIG. 6, the information processing system includes the graph conversion device 10, a storage device 20, an input device 30, and an output device 40. The graph conversion device 10, the storage device 20, the input device 30, and the output device 40 are communicatively connected via a network.

The graph conversion device 10 is an information processing device such as a circuit, a server computer, a personal computer or a mobile device that is equipped with a CPU (Central Processing Unit), a programmable device such as an FPGA (Field-Programmable Gate Array), a GPU (Graphics Processing Unit) or at least one or more of the above, for example.

The storage device 20 is a circuit or the like including a database, a server computer, and a memory. The storage device 20 stores a variety of information to be described later. In the example of FIG. 6, one storage device 20 is provided outside the graph conversion device 10, but a plurality of storage devices 20 may be provided inside or outside the graph conversion device 10.

The input device 30 is a device such as a keyboard, a mouse, or a touchscreen, for example. The input device 30 is used for operating the graph conversion device 10, the output device 40, and so forth. The output device 40 is a display device such as a display, for example.

The communication network is a general communication network constructed using communication lines, such as the Internet, a LAN (Local Area Network), a dedicated line, a telephone line, an in-house network, a mobile communication network, Bluetooth (registered trademark), and Wi-Fi (Wireless Fidelity), for example.

The graph conversion device 10 is a device that converts the content of learning data used for learning by the automated system design learning apparatus 50 (described later) that designs an ICT system. As shown in FIG. 6, the graph conversion device 10 includes a configuration collecting unit 11, a feature value generating unit 12, a distributed representation learning unit 13, and a converting unit 14. The respective functions of the configuration collecting unit 11, the feature value generating unit 12, the distributed representation learning unit 13 and the conversing means 14 can be realized by execution of a program for realizing the respective functions stored in the storage device by the arithmetic logic unit such as the CPU equipped in the information processing device configuring the graph conversion device 10. The respective components will be described below. The overview of each component will be described first, and the details thereof will be described later in the operation description.

The configuration collecting unit 11 is a means for collecting system configurations. To be specific, the configuration collecting unit executes, on a system requirement that is information representing a configuration of a system including an abstract part (element), a concretization process of converting the abstract part into a concrete part, generates a system concrete configuration that is information representing a configuration of the system including no abstract part, generates design path information representing a process of generating the system concrete configuration from the system requirement (information including system requirement, system configuration proposal in the process of generating the system configuration proposal from the system requirement, and system concrete configuration), and stores all the configurations included in the design path information.

The feature value generating unit 12 is a means that extracts information necessary for learning by the graph conversion device 10 from the system configurations collected by the configuration collecting unit 11 and generates a feature value of a component. The feature value generating unit 12 includes a type identification information extracting unit 121, a property information extracting unit 122, and a graph structure extracting unit 123.

The type identification information extracting unit 121 is a means for extracting type identification information that is information uniquely expressing components included in a system configuration, for each component.

The property information extracting unit 122 is a means for extracting information on a property (attribute) assigned to each of the components included in the system configuration.

The graph structure extracting units 123 is a means for extracting a structure when the system configuration is expressed by a graph (information on which elements are connected to each other).

The distributed representation learning unit 13 is a means that learns a distributed representation corresponding to each of the components included in the system configuration based on the information extracted by the feature value generating unit 12 (type identification information of element, property information of element, and information on configuration when system configuration is expressed by graph) and outputs a parameter necessary for calculating a distributed representation.

Here, “distributed representation”, “parameter for calculating distributed representation”, and “learning method for acquiring parameter” will be described.

First, a distributed representation corresponding to each component is a representation that expresses each component in a low-dimensional real-valued vector, and is information representing a feature of each component.

When comparing the distributed representations of certain two components, it can be determined that the closer the values of the respective constituents are, the similar the distributed representations of the two are. That is to say, in this case, it can be determined that the two components are similar components.

Conversely, it can be determined that the farther the values of the respective constituents of the distributed representations of the two components are, the less similar those two distributed representations are, and the two components are not similar components.

A distributed representation corresponding to a certain component is obtained by repeating an operation of adding the sequence of numerical values representing the feature value of the component and the sequence of numerical values representing the feature value of a component adjacent to the component with an appropriate weight, and updating the feature value of the component using the result of the addition.

A parameter necessary for calculating the distributed representation is here the weight described above. The parameter necessary for calculating the distributed representation determines the weight used for adding the feature value of a certain component and the feature value of a component adjacent to the component.

The parameter necessary for calculating the distributed representation mentioned above can be obtained by machine learning. A learning model to be machine-learned is a graph neural network that receives graph information in which each node and each edge in a configuration represented by a graph have feature values as an input, and that outputs graph information in the same format.

The abovementioned learning model receives a configuration in which a feature value is associated with each component as an input, then calculates a distributed representation of each component using the parameter, and finally outputs a predicted value of a label corresponding to each component based on the distributed representation. In the learning, the parameter is optimized so that the error between the predicted value of the label and a truth label is minimized. In addition, the truth label may be, for example, a sequence of numerical values that can uniquely identify a component, but is not limited thereto.

The above is the description of “distributed representation”, “parameter for calculating distributed representation” and “learning method for acquiring parameter” herein.

The converting unit 14 is a means that converts the system configuration input by the input device 30, using the parameter output as a result of the learning by the distributed representation learning unit 13, and outputs via the output device 40. To be specific, the converting unit 14 calculates distributed representations of the respective elements included in the system configuration by using the parameter obtained from the distributed representation learning unit 13, and assigns the distributed representations to the respective elements, thereby generating a configuration with distributed representation.

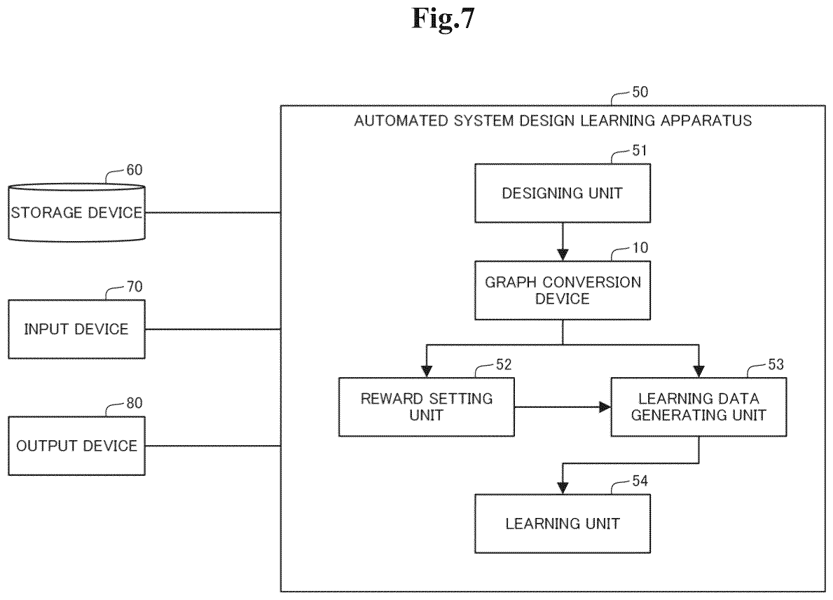

Next, using FIG. 7, a configuration of the automated system design learning apparatus 50 that is a learning apparatus generating a learning model automatically designing a system, and that includes the graph conversion device 10 as part of a function of the learning apparatus in the first example embodiment will be described. FIG. 7 is a diagram showing an example of an information processing system.

As shown in FIG. 7, the information processing system includes the automated system design learning apparatus 50, a storage device 60, an input device 70, and an output device 80. The automated system design learning apparatus 50, the storage device 60, the input device 70, and the output device 80 are communicatively connected via a network.

The automated system design learning apparatus 50 is, for example, an information processing apparatus such as a circuit, a server computer, a personal computer, or a mobile terminal, which is equipped with a CPU (Central Processing Unit), a programmable device such as an FPGA (Field-Programmable Gate Array), a GPU (Graphic Processing Unit), or one or more of the above.

The storage device 60 is a database, a server computer, a circuit having memory, and so forth. The storage device 60 stores various information, which will be described later. In the example of FIG. 7, one storage device 60 is provided outside the automated system design learning apparatus 50, but a plurality of storage devices 60 may be provided inside or outside the automated system design learning apparatus 50.

The input device 70 is, for example, a device such as a keyboard, a mouse, and a touchscreen. The input device 70 is used when operating the automated system design learning apparatus 50, the output device 80, and so forth. The output device 80 is, for example, a display device such as a display.

The communication network is, for example, a general communication network constructed using communication lines such as the Internet, a LAN (Local Area Network), a dedicated line, a telephone line, an in-house network, a mobile communication network, Bluetooth (registered trademark), and Wi-Fi (Wireless Fidelity).

The automated system design learning apparatus 50 is an apparatus that learns a learning model designing an ICT system. As shown in FIG. 7, the automated system design learning apparatus 50 includes a designing unit 51, the graph conversion device 10, a reward setting unit 52, a learning data generating unit 53, and a learning unit 54. The respective functions of the design unit 51, the graph conversion device 10, the reward setting unit 52, the learning data generating unit 53, and the learning unit 54 can be realized by execution of a program for realizing the respective functions stored in the storage device by the arithmetic logic unit such as the CPU equipped in the information processing apparatus configuring the automated system design learning apparatus 50. The respective components will be described below. The overview of each component will be described first, and the details thereof will be described later in the operation description.

The design unit 51 executes, on a system requirement that is information representing a configuration of a system including an abstract part (element), a concretization process of converting the abstract part into a concrete part, generates a system concrete configuration that is information representing a configuration of a system including no abstract part, and generates design path information representing a process of generating the system concrete configuration from the system requirement (information including system requirement, system configuration proposal in the process of deriving system concrete configuration from the system requirement, and system concrete configuration).

The graph conversion device 10 is a device that converts the content of learning data used for learning by the automated system design learning apparatus 50 that designs an ICT system as described above. How the graph conversion device 10 operates in the automated system design learning apparatus 50 will be described in detail in the operation description later.

The reward setting unit 52 sets a reward for each of the system requirement with distributed representation, the system configuration proposal with distributed representation and the system concrete configuration with distributed representation that are included in the design path information with distributed representation. Moreover, the reward setting unit 52 sets a reward for learning a system designing method based on the requirement.

The learning data generating unit 53 generates learning data in which the reward is associated with each of the system requirement with distributed representation, the system configuration proposal with distributed representation and the system concrete configuration with distributed representation that are included in the design path information with distributed representation.

The learning unit 54 learns a system designing method based on the requirement, based on the learning data.

### [Operation]

Next, the operation of the graph conversion device 10 and the automated system design learning apparatus 50 including the graph conversion device 10 in the first example embodiment will be described. In the following description, the drawings will be referred to as necessary. In the first example embodiment, an automated system design learning method is executed by causing the graph conversion device 10 and the automated system design learning apparatus 50 to operate. Therefore, the description of the automated system design learning method in the first example embodiment is equal to the description of the operation of the automated system design learning apparatus including the graph conversion device below.

First, the operation of the graph conversion device 10 will be described, followed by the operation of the automated system design learning apparatus 50 including the graph conversion device 10.

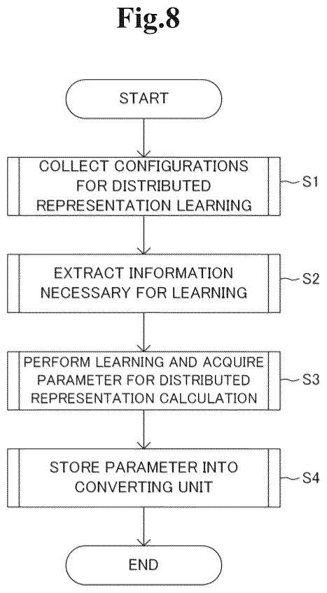

FIG. 8 is a diagram for describing an example of the operation of the graph conversion device 10 in the first example embodiment. First, the configuration collecting unit 11 collects system configurations as information to be the source of learning data for learning a distributed representation corresponding to each element of a configuration (step S1).

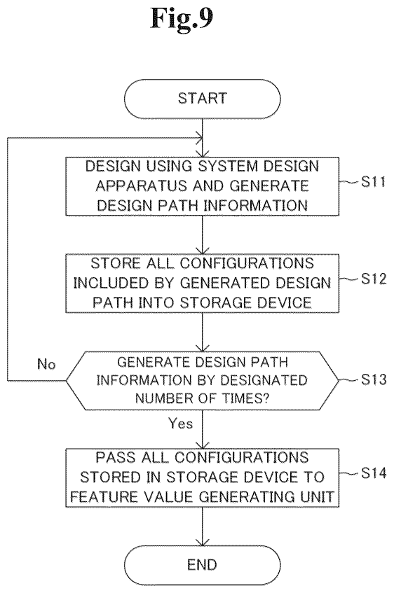

FIG. 9 is a diagram for describing an example of the operation of collecting system configurations for distributed representation learning (operation at step S1 described above).

First, the configuration collecting unit 11 performs system design, and generates design path information (step S11). For generating design path information, for example, a design function (designing unit 51) of the automated system design learning apparatus 50 can be used.

To be specific, the configuration collecting unit 11 executes, on a system requirement that is information representing a system configuration including an abstract part (element), a concretization process of converting the abstract part into a concrete part, generates a system concrete configuration that is information representing a system configuration including no abstract part, and generates design path information representing a process of generating the system concrete configuration from the system requirement (information including the system requirement, system configuration proposal in the process of deriving the system concrete configuration from the system requirement, and system concrete configuration).

Herein, it will be described as using the design function of the automated system design learning apparatus 50 for generating the design path information.

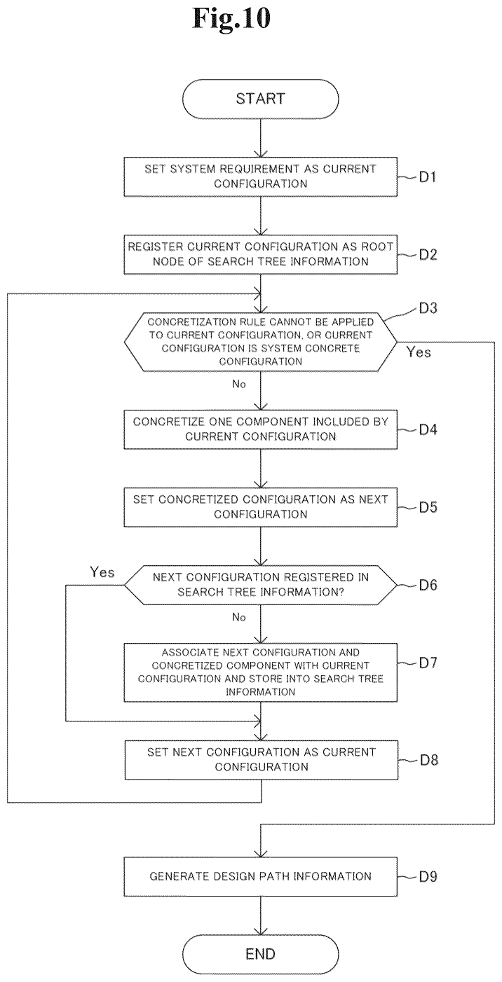

FIG. 10 is a diagram for describing the operation of generating the design path information.

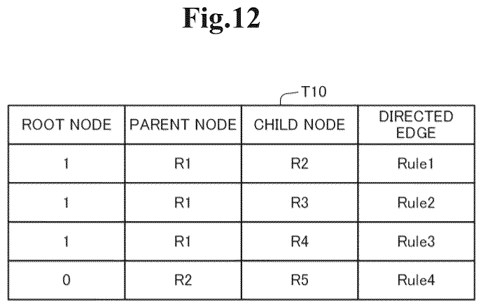

First, the configuration collecting unit 11 acquires a system requirement stored in advance in the storage device 20, and sets the acquired system requirement as a current configuration (step D1). Next, the configuration collecting unit 11 registers the current configuration as a root node of a search tree (step D2). To be specific, the configuration collecting unit 11 sets system requirement identification information for identifying the current configuration (system requirement) as the root node, and stores it into search tree information. The data structure of the search tree information will be described later with reference to FIG. 12.

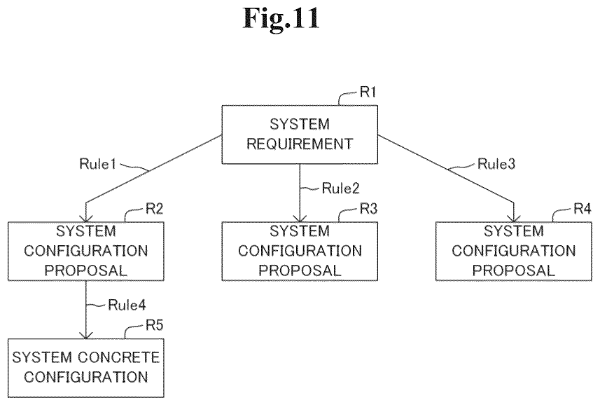

Here, FIG. 11 is a diagram for describing an example of the search tree. The search tree can be represented by a graph (search tree T1) as shown in FIG. 11. The root node referred to in the description of step D2 described above corresponds to the system requirement R1 in FIG. 11.

FIG. 12 is a diagram for describing an example of data structure of the search tree information. The data structure shown in FIG. 12 corresponds to the search tree of FIG. 11. In the example of FIG. 12, system requirement identification information “R1” associated with the system requirement R1 stored in the storage device 20 is stored in “parent node” of the search tree information T10, and moreover, “1” is stored as information indicating that the system requirement R1 is “root node”.

Next, in a case where no concretization rule can be applied to the current configuration or in a case where the current configuration is a system concrete configuration (step D3: Yes), the configuration collecting unit 11 proceeds to a process at step D9.

Further, in a case where there is a concretization rule applicable to the current configuration (No: step D3), the configuration collecting unit 11 repeats the processing from step D4 to step SD8.

Next, the configuration collecting unit 24 concretizes one of components included in the current configuration by executing a concretization process (step D4). Next, the configuration collecting unit 11 sets a configuration obtained by concretizing the abovementioned component at step D3 as a next configuration (step D5).

Next, in a case where the next configuration (concretized configuration (system configuration proposal)) is not stored in the search tree information (step D6: No), the configuration collecting unit 11 proceeds to a process at step D7. In a case where the next configuration (concretized configuration (system configuration proposal)) is stored in the search tree information (step D6: Yes), the configuration collecting unit 11 proceeds to a process at step D8.

Next, with a node representing the current configuration as a parent node, the next configuration (concretized configuration) as a child node, and an edge representing the concretized component (concretized component of concretization rule) as a directed edge, the configuration collecting unit 11 associates the next configuration and the concretized component with the current configuration, and stores into the search tree information (step D7).

For example, in a case where the current configuration is the system requirement R1 and the system configuration proposal R2 is generated from the system requirement R1, system configuration proposal identification information “R1” corresponding to the system requirement R1 in the search tree information T10, system configuration proposal identification information “R2” corresponding to the system configuration proposal R2 generated through the concretization process, and concretization identification information “Rule1” corresponding to the concretization rule used in the concretization process are associated and stored as shown in FIG. 12.

Further, in a case where the current configuration is the system configuration proposal R2 and a concrete configuration R5 is generated from the system requirement proposal R2, the system configuration proposal identification information “R2” of the search tree information T10, the system concrete configuration identification information “R5” associated with the concrete configuration generated through the concretization process, and the concretization rule identification information “Rule4” associated with the concretization rule used in the concretization process are associated and stored as shown in FIG. 12.

Next, the configuration collecting unit 11 sets the next configuration as a current configuration (step D8).

Next, the configuration collecting unit 11 generates a series of paths (design path information that stores configurations in chronological order) up to generation of the current system concrete configuration the system requirement, based on the system configurations (system requirement, system configuration proposal, system concrete configuration) obtained in the processing from step D1 to step D8 described above (step D9). Moreover, there is a case where no applicable concretization rule is left before the processing from step D1 to step D8 is repeated and the system concrete configuration is reached, and the design becomes a deadlock. In this case, the configuration collecting unit 11 generates a series of paths from the system requirement to the last reached system configuration proposal.

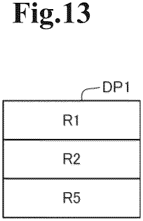

FIG. 13 is a diagram for explaining an example of the data structure of the design path information. In design path information DP1 shown in FIG. 13, the system requirement “R1”, the system configuration proposal “R2”, and the system concrete configuration “R5” shown in FIG. 11 are recorded in this order. That is to say, the design path information DP1 shows that, as one of the processes in system design, there is a series of design processes starting from the system requirement “R1”, passing through the system configuration proposal “R2”, and leading to the system concrete configuration “R5”.

Each of the configurations associated with the design path information (configurations such as R1, R2, and R5) is information replaced by a configuration with distributed representation generated by rewriting information held by each of the elements, as will be described later, and then used for generating learning data.

In the above manner, after generating the design path information (step S11 of FIG. 9), the configuration collecting unit 11 stores all the configurations included in the generated design path into the storage device (step S12).

Next, in a case where the design path information is generated for a designated number of times (step S13: Yes), the configuration collecting unit 11 passes all the configurations stored in the storage device to the feature value generating unit (step S14). In a case where the configuration collecting unit 11 has not generated the design path information for a designated number of times (step S13: No), the configuration collecting unit 11 performs the processing from step S11 to step S13 again.

The number of times the design path information is generated set in advance is determined by, for example, experiments, simulations, and the like.

In this manner, the configuration collecting unit 11 collects system configurations as information to be the source of learning data for learning a distributed representation corresponding to each of the elements of the configuration, and passes it to the feature value generating unit 12 (step S1).

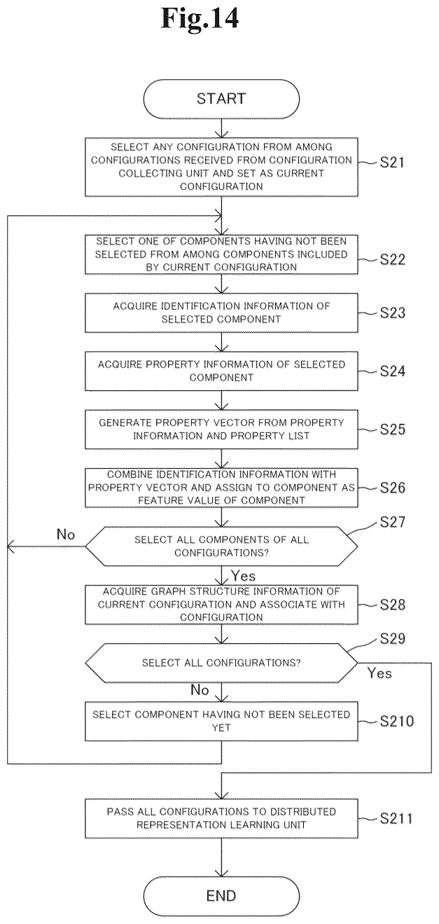

Next, the feature value generating unit 12 extracts information necessary for learning a distributed representation of each component included in the configuration, from the received system configuration (step S2 of FIG. 8). FIG. 14 shows an example of operation in which the feature value extracting unit 12 extracts information necessary for learning a distributed representation of each component and generates a feature value of the component.

First, the feature value generating unit 12 selects any configuration from among the configurations received from the configuration collecting unit 11 and sets it as a current configuration (step S21). Next, the feature value generating unit 12 selects one of components having not been selected from among components included in the current configuration (step S22).

Next, the type identification information extracting unit 121 acquires type identification information of the selected component (step S23). The type identification information is information that can uniquely identify the type of a component. For example, a one-hot vector can be considered as the type identification information. The one-hot vector is a vector in which one element is “1” and the other elements are “0”, and the respective elements of the vector correspond to the respective types one to one.

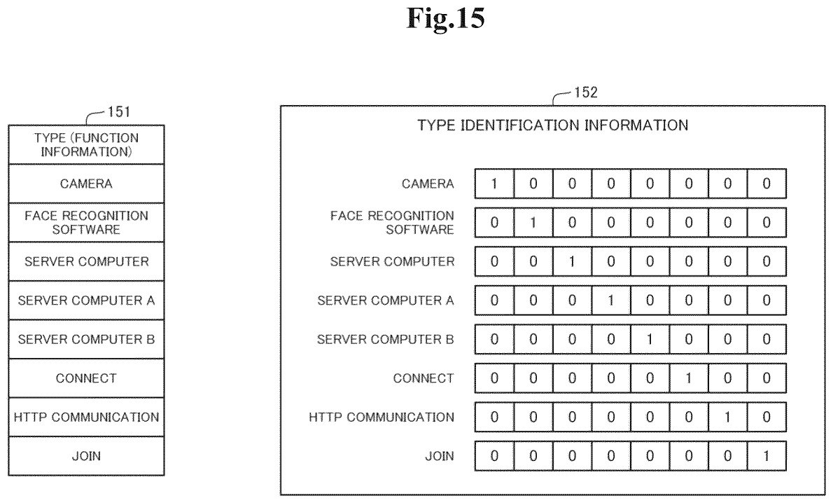

FIG. 15 is a diagram showing an example of the data structure of the type definition information and an example of types and identification information corresponding to the types. Reference numeral 151 in FIG. 15 denotes the type definition information. This shows type definition information used in design of the face recognition system shown in FIG. 1. In the example of the type definition information 151 shown in FIG. 15, the type names of “camera”, “face recognition software”, “server computer”, “server computer A”, “server computer B”, “connect”, “HTTP communication” and “join” representing the types are stored as “type (function information)” representing a type.

In the example of FIG. 15, the types used in the description of the face recognition system in FIG. 1 are shown as an example of the types stored, but the types stored in the type definition information are not limited to the types described in FIG. 15, and the types may be defined as types other than the types described in FIG. 15.

Further, reference numeral 152 in FIG. 15 is information representing the type identification information. The type identification information 152 is an example of a data structure of the type identification information corresponding to the type definition information 151 of FIG. 15 likewise. The type identification information 152 is information in which the type information representing the type is associated with an array having “0” and “1” in the elements as identification information corresponding to the type information. Such a data structure is generally referred to as a one-hot vector. The length of each array included by the type identification information shall be at least the same as or greater than the number of types stored in the type definition information. In addition, the elements of each array included by the type identification information correspond to the types stored in the type definition information in the order in which they are defined.

For example, in the case of type “camera” defined first in the type definition information, in an array (array “camera”) corresponding to “camera” in the type identification information, “1” is stored in the first element and “0” is stored in the remaining elements. For each of the types other than “camera”, an array in which “1” is stored in a position corresponding to the type and “0” is stored in the remaining positions is associated and stored.

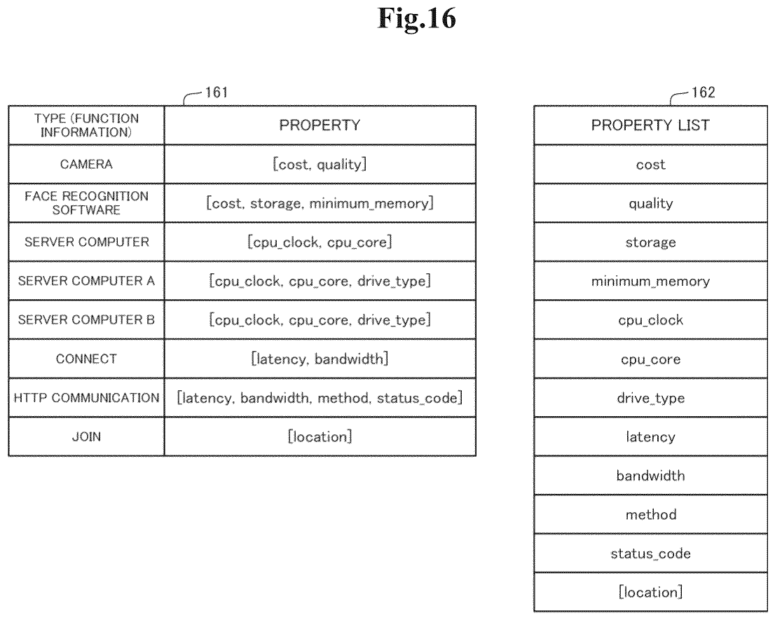

Next, the property information extracting unit 122 acquires property information of the selected component (step S24). The property information is information representing a characteristic or attribute associated with the type of each component. FIG. 16 shows an example of the type property information showing a type and a property defined for the type, and a property list that lists all the properties defined.

Reference numeral 161 of FIG. 16 is an example of a type and the data structure of type property information representing a property defined for the type.

For example, in the case of type “camera” defined first in the type property information 161, a property corresponding to “camera” of the type property information 161 is “cost (cost for purchase)” and “quality (image quality)”.

Likewise, for a type other than “camera”, it is possible to refer to a property defined for the type.

Further, reference numeral 162 in FIG. 16 is a diagram for showing an example of the data structure of the property list. The property list 162 is information in which all the properties defined in the type property information are recorded without excess or deficiency. The properties recorded in the property list are not duplicated, and the order in which the properties are recorded does not change unless there is a change in the type and property defined in the type definition information.

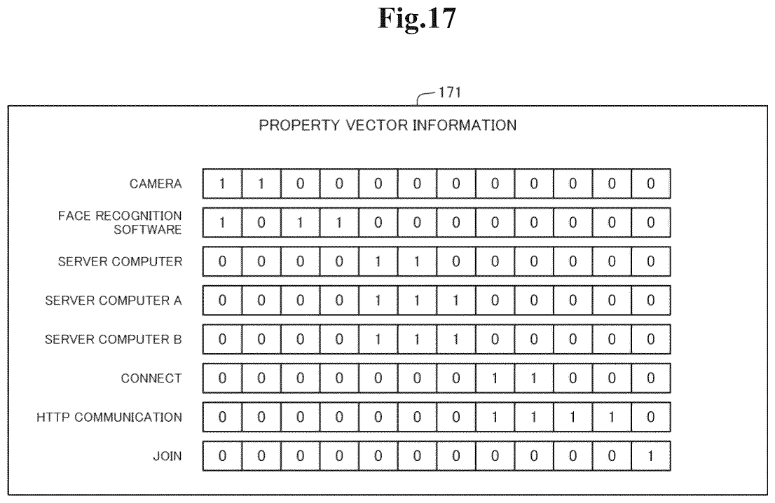

Next, the property information extracting unit 122 generates a property vector from the type property information and the property list (step S25). FIG. 17 is a diagram for showing an example of a property vector generated from the type property information and the property list.

Reference numeral 171 of FIG. 17 is a diagram that lists all property vectors that can be generated from the type property information 161 and the property list 162 shown in FIG. 16 for simplicity. Each of the elements of the property vector corresponds to each of the elements of the property list as shown in FIG. 16. That is to say, the length of the property vector is the same as the length of the property list. To be specific, the property vector is information in which the type information representing the type is associated with an array having elements in which the presence or absence of a property corresponding to the type information is represented by “0” or “1”. Such a data structure is generally referred to as a one-hot vector. At this time, the elements of each array included by the property vector correspond in the order of the properties stored in the property list.

For example, a property vector corresponding to “camera” shown first in the property vector information 171 is a vector in which the first and second elements are “1” and all the remaining elements are “0”. Referring to the properties defined in “camera” of the type property information 161, they are “cost” and “quality”. Here, referring to the property list 162, “cost” is recorded first, and “quality” is recorded second. That is to say, the fact that the first and second elements of the property vector of “camera”” shown in FIG. 17 are “1” indicates that the properties “cost” and “quality” are defined for type “camera”.

Although the property vector corresponding to type “camera” has been described in the above description, the property vector can be generated for any type other than type “camera”.

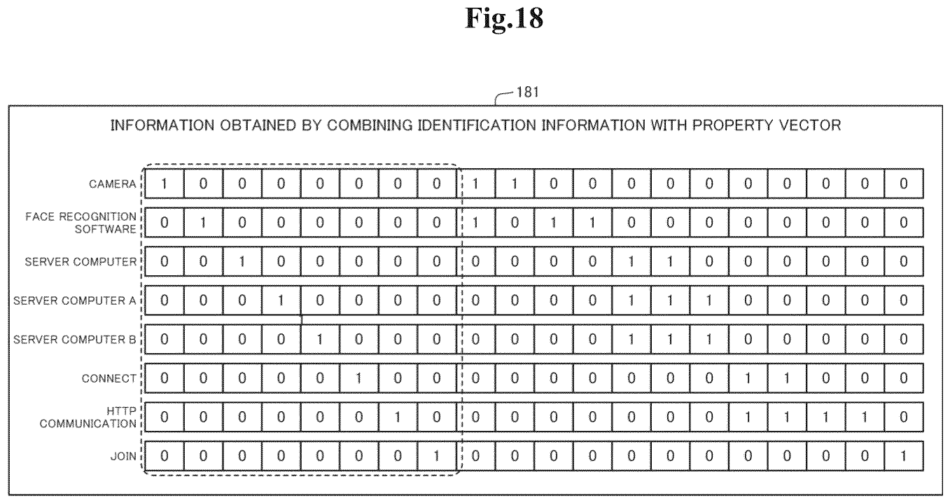

Next, the feature value generating unit 12 combines the type identification information and the property vector, and assigns this to the component as a feature value of the component (step S26). FIG. 18 is a diagram for showing information generated by combining the type identification information and the property vector. For simplicity, all the information that can be generated by the abovementioned method will be shown in a list. Information 181 in FIG. 18 is a combination of included information for each type based on the type identification information 152 shown in FIG. 15 and the property vector information 171 shown in FIG. 17.

Of the information 181 shown in FIG. 18, a part corresponding to the type identification information is shown surrounded by a dotted line. Taking type “camera” as an example, the type identification information of type “camera” is a vector in which the first element is “1” and the second to eighth elements are “0”, so that the element of a vector corresponding to type “camera” in the information 181 is like that. In addition, the property vector of type “camera” is a vector in which the first element and the second element are “1” and the subsequent elements are “0”. In the example shown in FIG. 18, the property vector is combined to the end of the type identification information, so that the ninth and tenth of the generated vector are “1” and the subsequent elements are “0”.

The feature value generating unit 12 does not generate the information 181 shown in FIG. 18 as it is. The information 181 in FIG. 18 is merely an example, showing a list of all information that can be generated for each type defined in the type definition information 151 in FIG. 15.

The feature value generating unit 12 assigns information generated by combining the type identification information and the property vector for each component in the manner as described above to the component as a feature value of the component.

Next, in a case where all the components of the current configuration have not been selected (step S27: No), the feature value generating unit 12 proceeds to the process at step S22, and executes the processes from step S22 to step S27 again. In a case where all the components of the current configuration have been selected (step S27: Yes), the feature value generating unit 12 proceeds to a process at step S28.

Next, the graph structure extracting unit 123 acquires the graph structure information of the current configuration (step S28). The graph structure information is information representing which components (nodes) are connected to each other by a relation (edge) in a configuration. The data format of the graph structure information is the same as the format shown in FIG. 3, and is information including the component identification information of all the nodes present in the configuration, the component identification information of all the edges, and the component identification information of the starting node and the component identification information of the end node of all the edges.

Next, in a case where all the configurations received from the configuration collecting unit 11 have not been selected (step S29: No), the feature value generating unit 12 proceeds to the process at step S210. In a case where all the configurations have been selected (step S29: Yes), the feature value generating unit 12 proceeds to the process at step S211.

The feature value generating unit 12 selects a configuration that has not been selected yet and sets it as a current configuration in the process at step S210. Upon completion of the process at step S210, the feature value generating unit 12 proceeds to the process at step S22, and executes the subsequent process again.

Finally, the feature value generating unit 12 passes all the configurations to a distributed representation learning unit at step S211. At the time of the process at step S210, in all the configurations passed to the distributed representation learning unit, to all the components included in those configurations, “information combining the type identification information and the property vector” corresponding thereto are assigned. Moreover, by the process at step S28, graph structure information of each configuration is associated with the configuration.

By performing the above-described operation, the graph conversion device 10 uses the feature value generating unit 12 to extract information necessary for learning a distributed representation and generates the feature value of a component.

Next, the distributed representation learning unit 13 performs learning using all the configurations received from the feature value generating unit 12 and the graph structure information associated with the respective configurations, and acquires a parameter necessary for calculating a distributed representation (step S3). Here, a learning model to be learned is a Graph Neural Network (GNN) that receives, as an input, graph information in which each node and each edge in a configuration represented by a graph have feature values, and that outputs graph information in the same format. As a learning method, a method aimed at acquiring a distributed representation of elements configuring a graph by learning, such as the techniques described in Non-Patent Literature 1 and Non-Patent Literature 2, is preferable, but is not limited to a specific learning method.

The description of the basic learning method that is not limited to a specific method is as described above for the distributed representation learning unit 13 with reference to FIG. 6.

To be specific, for example, a method can be considered where: each node (component) is given a feature value composed of type identification information and a property vector; after a distributed representation of each node is calculated in consideration of the relation and adjacency information between nodes, a model to predict the component identification information of an adjacent node based on that is prepared; and then learning is performed to minimize the binary cross-entropy error between the predicted value and numerical values representing the actual component identification information (for example, a vector with elements of 0 and 1).

Finally, the converting unit 14 stores the parameter acquired by the learning by the distributed representation learning unit 13, necessary for calculating a distributed representation.

The converting unit 14 having received the parameter necessary for learning a distributed representation can calculate a distributed representation of each component included in graph data (one or more system configurations) input through the input device 30. Moreover, the converting unit 14 can generate a configuration with distributed representation by assigning the calculated distributed representation of each component to the component, and output it through the output device 40.

As described above, the graph conversion device 10 can learn a parameter for calculating a distributed representation of each component by extracting necessary information from a configuration and using it as learning data, generate a configuration with distributed representation by assigning the distributed representation of each component of the input graph data to the component, and output the configuration with distributed representation.

Next, the operation of the automated system design learning apparatus 50 including the graph conversion device 10 will be described.

Herein, the graph conversion device 10 is a device incorporated inside the automated system design learning apparatus 50 for the purpose of reducing time costs since the automated system design learning apparatus 50 makes a change to learning data used for learning so that relearning of the system design apparatus that would have been necessary if a new element had been added is not necessary. The change to be made to the learning data by the automated system design learning apparatus 50 is to assign a distributed representation corresponding to a component included by a configuration to the component. The graph conversion device 10 shall have completed learning so as to be able to calculate an appropriate distributed representation before the automated system design learning apparatus 50 is operated.

Further, the automated system design learning apparatus 50 is a device that makes system design more efficient by learning so as to be able to select an appropriate concretization rule from among the applicable concretization rules described above. Based on the above, the operation of the automated system design learning apparatus 50 including the graph conversion device 10 will be described.

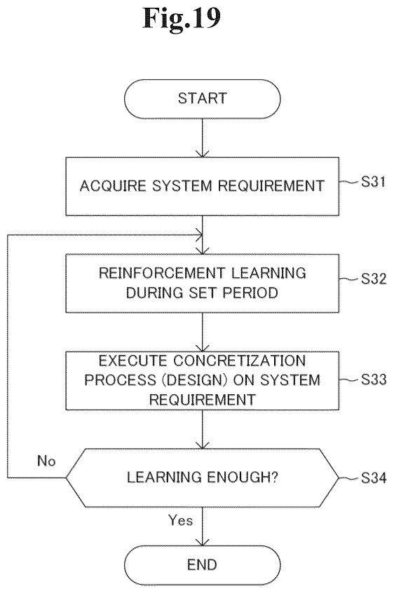

FIG. 19 is a diagram for showing an example of the operation of the automated system design learning apparatus 50 including the graph conversion device 10 in the first example embodiment. First, the automated system design learning apparatus 50 acquires a system requirement to be a learning target from the storage device 60 (step S31).

Next, the automated system design learning apparatus 50 executes reinforcement learning during a preset period using the learning target system requirement (step S32). Consequently, a learning model is generated. For example, in a case where a neural network is used for reinforcement learning, the learning model is the neural network.

The preset learning period is determined by, for example, experiments, simulations, and the like. In addition, the learning period may be the number of times of learning, instead of the learning period. The number of times of learning is, for example, the number of updates of the weight of the neural network when the neural network is used.

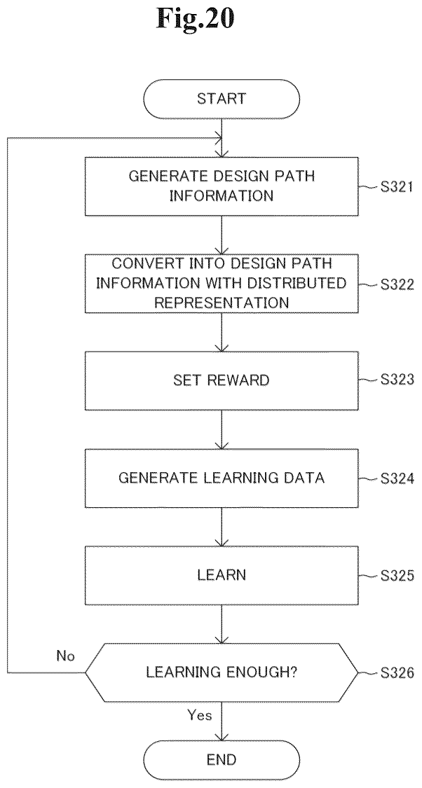

Here, the details of the learning operation that is the above process at step S32 will be described later with reference to FIG. 20. In the learning, an ICT system designing method will be learned.

First, the designing unit 51 generates design path information using the system requirement (step S321). To be specific, the designing unit 51 generates design path information as shown in the flowchart of FIG. 10. Since the operation of the designing unit 51 to generate the design path information is the same as that described using FIG. 10 as the description of the example of the operation of the configuration collecting unit 11 mentioned above, the description will be omitted here.

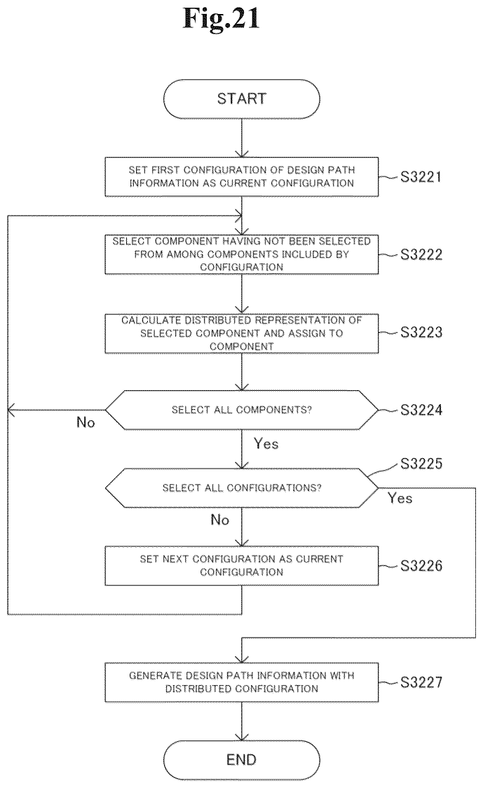

After the designing unit 51 generates the design path information (step S321 of FIG. 20), the automated system design learning apparatus 50 uses the graph conversion device 10 to convert it into design path information with distributed representation (step S322). To be specific, the graph conversion device 10 generates design path information with distributed representation as shown in a flowchart of FIG. 21. In addition, the process of generating the design path information with distributed representation by the graph conversion device 10 to be described below is performed for each path, which is a series of design processes.

First, the graph conversion device 10 set the first configuration of the design path information as a current configuration (step S3221). Next, the graph conversion device 10 selects a component having not been selected from among components included by the configuration (step S3222).

Next, the graph conversion device 10 calculates a distributed representation of the selected component and assigns it to the component (step S3223). Assigning a distributed representation to a component means enabling the distributed representation of the component to be referenced. Next, in a case where all the components of the current configuration have not been selected (step S3224: No), the graph conversion device 10 proceeds to the process at step S3222, and executes the processes from step S3222 to step S3224 again. In a case where all the components of the current configuration have been selected (step S3224: Yes), the graph conversion device 10 proceeds to a process at step S3225.

Next, in a case where all the configurations of the design path information have not been selected (step S3225: No), the graph conversion device 10 proceeds to a process at step S3226. At step S3226, the graph conversion device 10 sets the next configuration of the design path information as a current configuration. After that, the graph conversion device 10 proceeds to the process at step S3222. In a case where all the configurations of the design path information have been selected (step S3225: Yes), the graph conversion device 10 proceeds to a process at step S3227.

Finally, the graph conversion device 10 generates design path information with distributed representation (step S3227).

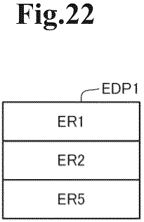

FIG. 22 is a diagram for describing an example of the data structure of the design path information with distributed representation. Design path information with distributed representation EDP1 shown in FIG. 22 represents a configuration in which a distributed representation is given to a component of each of the configurations associated with the design path information DP1 shown in FIG. 13. That is to say, a system requirement with distributed representation “ER1”, a system configuration proposal with distributed representation “ER2”, and a system concrete configuration with distributed representation “ER5” shown in FIG. 22 refer to configurations in which distributed representations are assigned to the components of the system requirement “R1”, the system configuration proposal “R2”, and the system concrete configuration “R5”.

Thus, the graph conversion device 10 converts design path information to design path information with distributed representation (step S322 of FIG. 20).

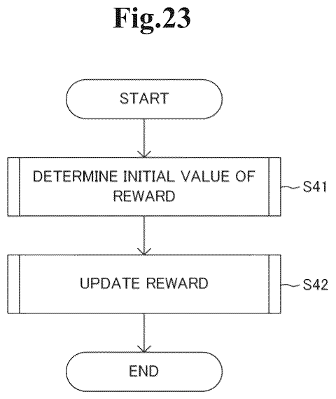

Next, the reward setting unit 52 sets a reward for each system configuration with distributed representation of the design path information with distributed representation (the system requirement with distributed representation, or the system configuration proposal with distributed representation, or the system concrete configuration with distributed representation, which are mentioned above) (step S323 of FIG. 20). To be specific, the reward setting unit 52 sets a reward as shown in a flowchart of FIG. 23. A reward setting process by the reward setting unit 52 to be described below is performed for each path, which is a series of design processes.

Here, in the system design described in the present disclosure, it is important to apply an appropriate concretization rule to a configuration proposal and efficiently reach a system concrete configuration. Therefore, a process of giving a probability that each configuration proposal can reach a concrete configuration as a reward by using design path information with distributed representation is performed.

First, the reward setting unit 52 determines the initial value of an update candidate reward (step S41). Specifically, in a case where the last configuration of the design path information with distributed representation is a system concrete configuration with distributed representation, the reward setting unit 52 sets, as the initial value of the update candidate reward, the reward of the system concrete configuration with distributed representation to “1”, for example, and in a case where it is not a system concrete configuration with distributed representation, the reward setting unit 52 sets the reward corresponding to the last configuration to “0”, for example.

Here, the update candidate reward described above is a value used when updating the value of a reward obtained by each system configuration (system configuration with distributed representation) of the design path information with distributed representation at step S42, which will be described later.

In the case of the example of FIG. 22, the last configuration of the design path information with distributed representation EDP1 is the system concrete configuration with distributed representation “ER5”, so that the reward “1” is associated with “ER5” representing the system concrete configuration with distributed representation of the design path information with distributed representation EDP1 in the process at step S41.

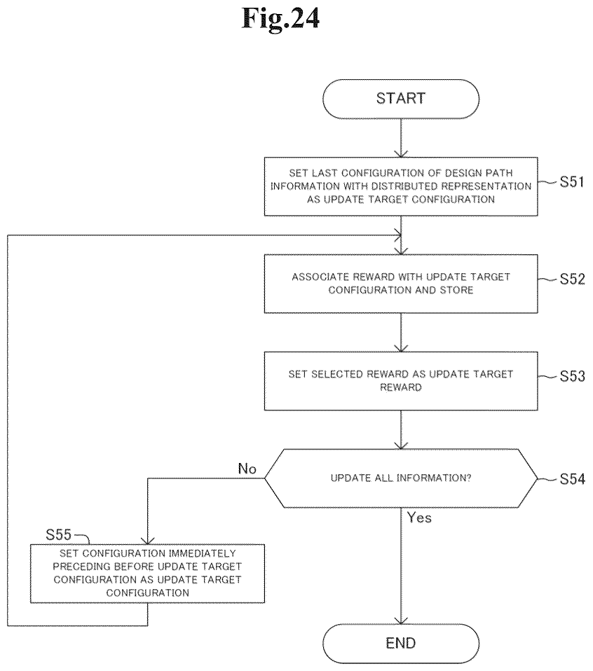

Next, the reward setting unit 52 updates the reward of each system configuration (system configuration with distributed representation) included in the design path information with distributed representation (step S42). Specifically, the reward setting unit 52 performs a process to update the reward as shown in a flowchart of FIG. 24.

First, the reward setting unit 52 sets the last configuration (system configuration with distributed representation) in the design path information with distributed representation as an update target configuration (step S51). Next, the reward setting unit 52 compares a reward associated with the update target configuration with an update candidate reward, selects the larger reward, and stores the selected reward in association with the update target configuration (step S52). Next, the reward setting unit 52 sets the reward selected at step S52 (the larger reward in comparison) as the update candidate reward (step S53).

Next, in a case where the reward update process has not been performed on all the configurations in the design path information with distributed representation (in a case where execution of the reward update process has not finished to the first configuration in the design path information with distributed representation) (step S54: No), the reward setting unit 52 sets a configuration immediately preceding the current update target configuration as an update target configuration (step S55), and proceeds to the process at step S52.

Further, in a case where the reward update process has been executed on all the configurations in the design path information with distributed representation (in a case where the reward update process has finished to the first configuration in the design path information with distributed representation) (step S54: Yes), the reward setting unit 52 ends the process at step S42 shown in FIG. 24.

To be specific, as the update candidate reward to be set at step S42 is, after comparison between the reward associated with the update target configuration and the evaluation of the update candidate, it is regarded as “0” if the former reward is not present yet (if it is not associated) before the comparison. Then, after the comparison, the update is performed by setting the larger one as the reward associated with the update target configuration and the update candidate reward. After that, the update target configuration is updated, and this process is repeated.

For example, a reward is not associated with any of the configurations at first, so that in the example of FIG. 22, “ER5” is the first update target configuration at step S51. Since a reward has not been associated with “ER5” yet, its value is considered to be “0”. In that case, the update candidate reward has been initialized to “1” at step S41, so that “0” and “1” are compared with each other, and the larger reward “1” is associated with “ER5”.

Next, “ER2” is set as an update target configuration, and the same processing as the abovementioned processing is executed again. After that, further, “ER1” is set as an update target configuration, and the same processing as the abovementioned processing is repeated.

As another example, in a case where, starting as the first update candidate configuration (a configuration that is not a system concrete configuration with distributed representation), it is not a concrete configuration, the update candidate reward is initialized to “0”, and in a case where a reward “1” is associated with the next configuration, “0” and “1” are compared and the value of the update candidate reward is updated to “1”, which is larger.

Specifically, in the process at step S42, data (reward) for learning the evaluation values of the configurations “ER2” and “ER1” in the design process based on the evaluation value of the configuration “ER5” at the end of the design is generated from the process performed at step S51. At this time, if larger data (reward) has been obtained previously, it is given priority, so that it is compared with the reward stored in association with the configuration, and the larger one is left.

In the above description, the larger one is left and propagated upward (“ER1” when seen from “ER2”) because it is known that a transition can be made from “ER1” to “ER2”. What to be learned is an expected reward to be obtained when the best option is kept to be selected, and it is known that a transition can be made from “ER1” to “ER2” when an appropriate concretization rule is applied. Therefore, when the reward associated with “ER2” is greater, the reward of “ER5” should be propagated to “ER1” as a priority.

A transition from “ER1” to “ER2” does not necessarily occur, but there is a possibility thereof. For example, in the example of FIG. 11, there is a possibility of transition to “ER3” or “ER4”. However, the automatic design function can select which transition to make, so that a larger reward in comparison is propagated upward.

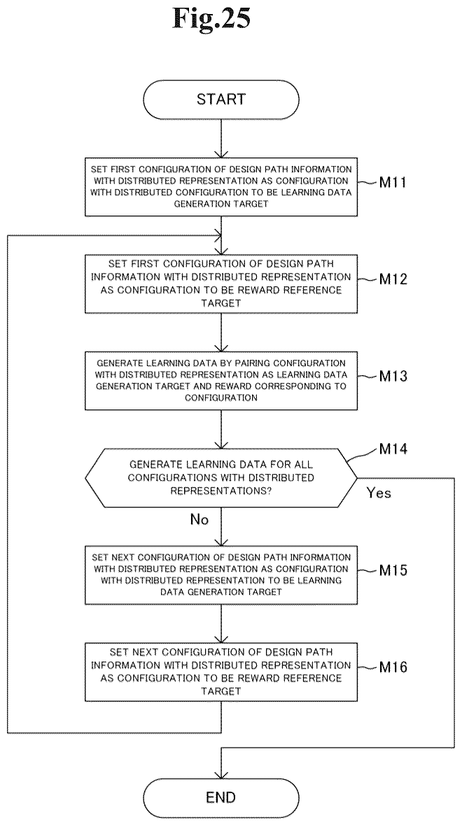

After setting the reward in the above manner (step S323 in FIG. 20), the learning data generating unit 53 generates learning data by associating the design system configuration with distributed representation and the reward for the design path information with distributed representation, and stores the generated learning data into the storage device 60 (step S324 in FIG. 20). Specifically, the learning data generating unit 53 generates learning data as shown in a flowchart of FIG. 25.

First, the learning data generating unit 53 sets the first configuration of the design path information with distributed representation as a configuration with distributed representation to be a learning data generation target (step M11). Next, the learning data generating unit 53 sets the first configuration of the design path information with distributed representation as a configuration to be a reward reference target (step M12).

Next, the learning data generating unit 53 generates learning data by pairing the configuration with distributed representation to be the target for generating learning data and the reward corresponding to the configuration (the reward set at step 52 of FIG. 24), and stores the generated learning data into the storage device 60 (step M13).

Next, in the case of having not generated learning data for all the configurations included in the design path information with distributed representation (in the case of having not finished generating learning data to the last configuration in the design path information with distributed representation) (step M14: No), the learning data generating unit 53 proceeds to a process at step M15. In the case of having generated learning data for all the configurations included in the design path information with distributed representation (in the case of having finished generating learning data to the last configuration in the design path information with distributed representation) (step M14: Yes), the learning data generating unit 53 ends the process to generate learning data.

Next, the learning data generating unit 53 sets the next configuration in the design path information with distributed representation as a learning data generation target configuration (step M15).

Next, the learning data generating unit 53 sets the next configuration in the design path information with distributed representation as a reward reference target configuration (step M16).

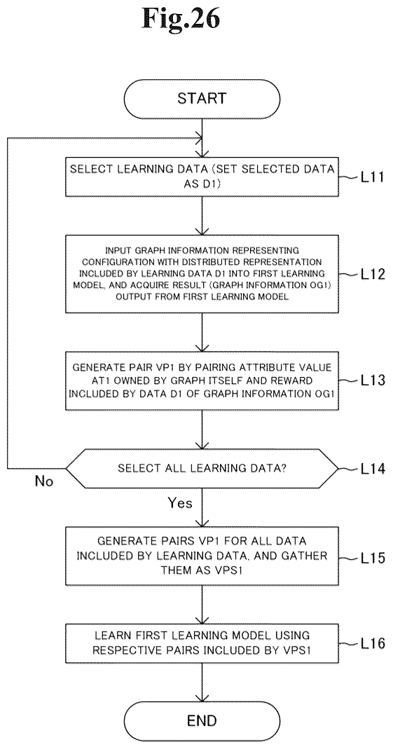

After the learning data is generated in the above manner (step S324 of FIG. 20), the learning unit 54 performs learning based on the learning data (step S325 of FIG. 29). Specifically, the learning unit 54 performs learning of a learning model as shown in a flowchart of FIG. 26.

Here, a learning model to learn is a GNN (Graph Neural Network) that receives graph information in which each node and edge in a graph and the graph itself have attribute values as an input and outputs graph information in the same format.

First, the learning unit 54 selects one learning data D1 from among the learning data generated as described above (step L11). Next, the learning unit 54 inputs graph information representing a configuration with distributed representation included by the learning data D1 into a first learning model, and acquires a result (graph information OG1) output from the learning model (step L12).

Next, the learning unit 54 generates a pair VP1 by pairing an attribute value At1 of the graph itself and a reward included by the data D1 of the graph information OG1 (step L13).

Next, in the case of having selected all the learning data (step L14: Yes), the learning unit 54 proceeds to a process at step L15. In the case of having not selected all the learning data (step L14: No), the learning unit 54 proceeds to the process at step L11, and executes the processes up to step L13 again.

Next, the learning unit 54 generates pairs VP1 for all the data included in the learning data and gathers as VPS1 (step L15).

Then, the learning unit 54 learns the first learning model using the respective pairs included by VPS1 (step L16). To be specific, the learning unit 54 uses the respective pairs included by VPS1 to train the learning model so as to minimize a loss function with the mean squared error between the attribute value and the determined reward as the loss function.

As described above, during a learning period set in advance, the processes from step S321 to step S325 shown in FIG. 20 are repeated to perform reinforcement learning (step S32 in FIG. 19).

Then, using the learning model at the current moment generated through the abovementioned reinforcement learning, the automated system design learning apparatus 50 executes a concretization process (design) on the system requirement (step S33 of FIG. 19).

The concretization process (design) is a process to concretize an abstract part (component) included by a system requirement. By repeatedly executing the concretization process, it is possible to finally derive a system concrete configuration including only a concrete part. An example of the concretization process is as shown in FIG. 1.

Subsequently, in a case where it is determined that learning is enough based on the result at step S33 (step S34: Yes), the automated system design learning apparatus 50 ends reinforcement learning at step S32. In a case where it is determined that learning is not enough (step S34: No), the automated system design learning apparatus 50 repeats the processes at steps S32 and S33 until it is determined that learning is enough.

In the determination at step S34, it is determined to be enough, for example, when the number of steps of search is equal to or less than a preset threshold value A. Also, in the determination at step S34, it may be determined to be enough when the number of steps of search performed at step S33 previously is equal to or less than a preset threshold value B consecutively for a specified number of times. However, the determination at step S34 is not limited to the abovementioned methods.

The number of steps of search described above depends on the method for design at step S33. The number of steps of search is the number of times that a concretization rule is applied to a system requirement or a system configuration proposal until a system concrete configuration is derived from the system requirement. The number of steps of search can also be expressed as the number of system configuration proposals actually reached during the design.

As described above, according to this example embodiment, when a system design is performed by adding a new element, learning is performed by converting learning data into a format that allows evaluation of an unlearned element using experience on previously learned elements, so that relearning of the system design apparatus that would have been necessary if a new element had been added is not necessary, thereby reducing time costs.

### Second Example Embodiment

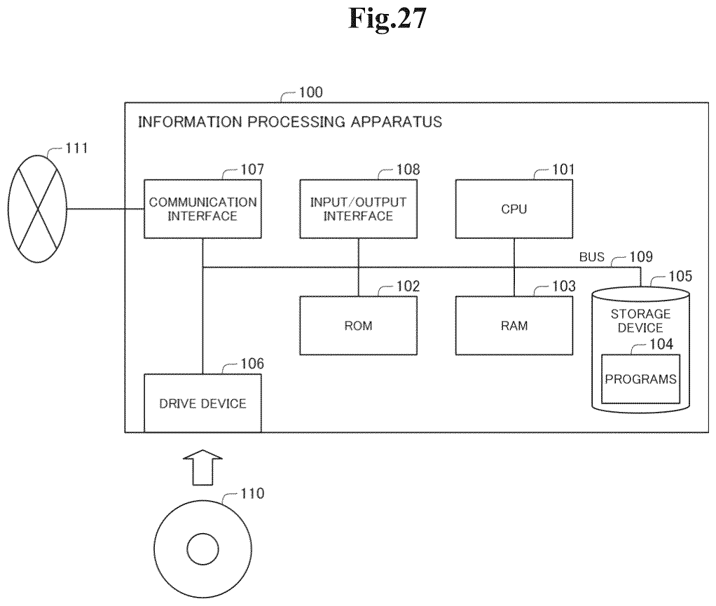

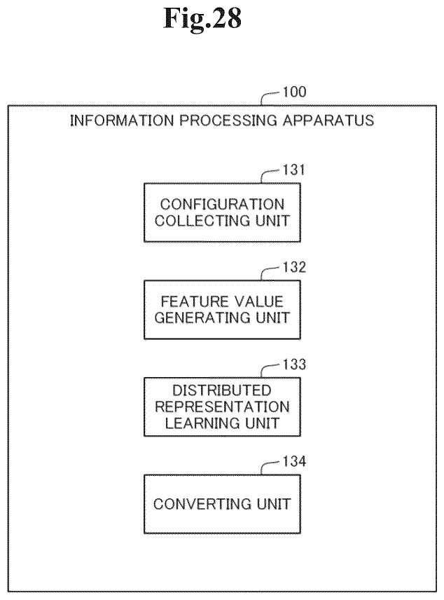

Next, a second example embodiment of the present disclosure will be described with reference to the drawings. In this example embodiment, the overview of the configuration of the automated system design learning apparatus described in the above example embodiment will be shown. FIGS. 27 and 28 are diagrams for describing the configuration, and these drawings may be relevant to any of the example embodiments.

First, the hardware configuration of an information processing apparatus 100 will be described with reference to FIG. 27. The information processing apparatus 100 is configured with a general information processing apparatus and, as an example, has the following hardware configuration including;
a CPU (Central Processing Unit) 101 (arithmetic logic unit),
a ROM (Read Only Memory) 102 (memory unit),
a RAM (Random Access Memory) 103 (memory unit),
programs 104 loaded to the RAM 103,
a storage device 105 storing the programs 104,
a drive device 106 performing reading from and writing into a storage medium 110 outside the information processing apparatus,
a communication interface 107 connected to a communication network 111 outside the information processing apparatus,
an input/output interface 108 inputting and outputting data, and
a bus 109 connecting the respective components.

FIG. 27 shows an example of the hardware configuration of the information processing apparatus serving as the information processing apparatus 100, and the hardware configuration of the information processing apparatus is not limited to the abovementioned case. The information processing apparatus may be configured with part of the above configuration, for example, may omit the drive device 106. Moreover, the information processing apparatus can use, instead of the abovementioned CPU, a GPU (Graphic Processing Unit), a DSP (Digital Signal Processor), an MPU (Micro Processing Unit), an FPU (Floating point number Processing Unit), a PPU (Physics Processing Unit), a TPU (Tensor Processing Unit), a quantum processor, a microcontroller, a combination thereof, or the like.

Then, by causing the CPU 101 to acquire and execute the programs 104, the information processing apparatus 100 can construct and include a configuration collecting unit 131, a feature value generating unit 132, a distributed representation learning unit 133, and a converting unit 134 shown in FIG. 28. The programs 104 are, for example, stored in advance in the storage device 105 or the ROM 102, and are loaded to the RAM 103 and executed by the CPU 101 as required. The programs 104 may be provided to the CPU 101 via the communication network 111, or may be stored in advance in the storage medium 110 and be read out by the drive device 106 and provided to the CPU 101. However, the configuration collecting unit 131, the feature value generating unit 132, the distributed representation learning unit 133, and the converting unit 134 mentioned above may be constructed using dedicated electronic circuits for realizing such means.

The configuration collecting unit 131 collects system configuration information included by design path information representing a design process of the system configuration information representing a system configuration including a combination of elements designed by converting an abstract element to a concrete element using a preset concretization rule. The feature value generating unit 132 generates a feature value of the element in the system configuration information included by the design path information. The distributed representation learning unit acquires, by machine learning, a parameter for calculating a distributed representation of the element by using graph structure information representing a relation between the elements in the system configuration information by a graph structure and the feature value of the element. The converting unit generates design path information with distributed representation by calculating using the parameter the distributed representation of the element within the system configuration information included by the design path information, which is a learning target of a learning model machine-learned so as to convert an abstract element into a concrete element using the aforementioned concretization rule, and assigning the distributed representation.

Configured as described above, the present disclosure enables the reduction of time-related costs when performing system design.

Note that at least one or more functions of the configuration collecting unit 131, the feature value generating unit 132, the distributed representation learning unit 133, and the converting unit 134 may be performed by the information processing apparatus installed and connected anywhere on the network, that is, may be performed by so-called cloud computing.

Further, the abovementioned programs can be stored using various types of non-transitory computer-readable mediums and provided to a computer. The non-transitory computer-readable mediums include various types of tangible storage mediums. Examples of the non-transitory computer-readable mediums include a magnetic recording medium (e.g., floppy disk, magnetic tape, hard disk drive), a magneto-optical recording medium (e.g., magneto-optical disk), a CD-ROM (Read Only Memory), a CD-R, a CD-R/W, and a semiconductor memory (e.g., mask ROM, PROM (Programmable ROM), EPROM (Erasable PROM), flash ROM, and RAM (Random Access Memory)). The programs may also be provided to a computer by various types of transitory computer-readable mediums. Examples of the transitory computer-readable mediums include an electric signal, an optical signal, and an electromagnetic wave. The temporary computer-readable medium can provide the program to a computer via a wired communication path such as an electric wire or an optical fiber, or via a wireless communication path.

Although the present disclosure has been described above with reference to the example embodiments and so forth, the present disclosure is not limited to the above example embodiments. The configuration and details of the present disclosure can be changed in various manners that can be understood by one skilled in the art within the scope of the present disclosure. The above example embodiments can be combined with another example embodiment as required.

### SUPPLEMENTARY NOTES

The whole or part of the example embodiments disclosed above can be described as in the supplementary notes. Below, the overview of the configurations of the information processing apparatus, the information processing method, and the program in the present disclosure will be described. However, the present disclosure is not limited to the following configurations.

### Supplementary Note 1

An information processing apparatus comprising:
a configuration collecting unit that collects system configuration information included by design path information representing a process of designing the system configuration information, the system configuration information representing a system configuration including a combination of elements designed by converting an abstract element into a concrete element using a preset concretization rule;
a feature value generating unit that generates a feature value of the element in the system configuration information included by the design path information;
a distributed representation learning unit that acquires, by machine learning, a parameter for calculating a distributed representation of the element using graph structure information representing a relation between the elements in the system configuration information by a graph structure and the feature value of the element; and
a converting unit that, for the design path information to be a target for learning by a learning model to be machine-learned so as to convert the abstract element into the concrete element using the concretization rule, generates design path information with distributed representation by calculating the distributed representation of the element in the system configuration information included by the design path information using the parameter and then assigning the distributed representation to the design path information.

### Supplementary Note 2

The information processing apparatus according to supplementary note 1, wherein the feature value generating unit generates property information representing a characteristic of the element as the feature value.

### Supplementary Note 3

The information processing apparatus according to supplementary note 1, wherein the feature value generating unit generates type information representing a type of the element as the feature value.

### Supplementary Note 4

The information processing apparatus according to supplementary note 1, wherein the feature value generating unit generates property information representing a characteristic of the element and type information representing a type of the element as the feature value.

### Supplementary Note 5

The information processing apparatus according to supplementary note 4, wherein the feature value generating unit expresses the property information by an array indicating presence or absence of the characteristic of the element and also expresses the type information by an array indicating presence or absence of the type of the element, and connects the array of the property information and the array of the type information to generate as the feature value.

### Supplementary Note 6

The information processing apparatus according to supplementary note 1, wherein when the feature value is associated with the element in the graph structure information and is input, the distributed representation learning unit acquires the parameter using a model that outputs the graph structure of the element accompanied by calculation of the distributed representation of the element.

### Supplementary Note 7

The information processing apparatus according to supplementary note 6, wherein when the feature value is associated with the element in the graph structure information and is input, the distributed representation learning unit acquires the parameter by learning, using a preset correct value of an output, a model that outputs a predicted value of the graph structure of the element accompanied by calculation of the distributed representation of the element.

### Supplementary Note 8

The information processing apparatus according to supplementary note 1, comprising:
a reward setting unit that, for each of the system configuration information included by the design path information with distributed representation, sets a reward for the system configuration information based on whether or not the element included by the system configuration information is a concrete element; and
a learning data generating unit that generates each of the system configuration information included by the design path information with distributed representation and the reward set for the system configuration information, as learning data to be machine-learned for generating a learning model that converts the system configuration information based on the concretization rule.

### Supplementary Note 9

An information processing method by an information processing apparatus, the information processing method comprising:
collecting system configuration information included by design path information representing a process of designing the system configuration information, the system configuration information representing a system configuration including a combination of elements designed by converting an abstract element into a concrete element using a preset concretization rule; generating a feature value of the element in the system configuration information included by the design path information;
acquiring, by machine learning, a parameter for calculating a distributed representation of the element using graph structure information representing a relation between the elements in the system configuration information by a graph structure and the feature value of the element; and
for the design path information to be a target for learning by a learning model to be machine-learned so as to convert the abstract element into the concrete element using the concretization rule, generating design path information with distributed representation by calculating the distributed representation of the element in the system configuration information included by the design path information using the parameter and then assigning the distributed representation to the design path information.

### Supplementary Note 10

A program comprising instructions for causing an information processing apparatus to execute processes to:
collect system configuration information included by design path information representing a process of designing the system configuration information, the system configuration information representing a system configuration including a combination of elements designed by converting an abstract element into a concrete element using a preset concretization rule;
generate a feature value of the element in the system configuration information included by the design path information;
acquire, by machine learning, a parameter for calculating a distributed representation of the element using graph structure information representing a relation between the elements in the system configuration information by a graph structure and the feature value of the element; and
for the design path information to be a target for learning by a learning model to be machine-learned so as to convert the abstract element into the concrete element using the concretization rule, generate design path information with distributed representation by calculating the distributed representation of the element in the system configuration information included by the design path information using the parameter and then assigning the distributed representation to the design path information.

DESCRIPTION OF REFERENCE NUMERALS

| | |
|---|---|
| 10 | graph conversion device |
| 11 | configuration collecting unit |
| 12 | feature value generating unit |
| 121 | type identification information extracting unit |
| 122 | property information extracting unit |
| 123 | graph structure extracting unit |
| 13 | distributed representation learning unit |
| 14 | converting unit |
| 20 | storage device |
| 30 | input device |
| 40 | output device |
| 50 | automated system design learning apparatus |
| 51 | designing unit |
| 52 | reward setting unit |
| 53 | learning data generating unit |
| 54 | learning unit |
| 60 | storage device |
| 70 | input device |
| 80 | output device |
| 100 | information processing apparatus |
| 101 | CPU |
| 102 | ROM |
| 103 | RAM |
| 104 | programs |
| 105 | storage device |
| 106 | drive device |
| 107 | communication interface |
| 108 | input/output interface |
| 109 | bus |
| 110 | storage medium |
| 111 | communication network |
| 131 | configuration collecting unit |
| 132 | feature value generating unit |
| 133 | distributed representation learning unit |
| 134 | converting unit |

1. An information processing apparatus comprising:
at least one memory storing processing instructions; and
at least one processor configured to execute the processing instructions to:
collect system configuration information included by design path information representing a process of designing the system configuration information, the system configuration information representing a system configuration including a combination of elements designed by converting an abstract element into a concrete element using a preset concretization rule;
generate a feature value of the element in the system configuration information included by the design path information;
acquire, by machine learning, a parameter for calculating a distributed representation of the element using graph structure information representing a relation between the elements in the system configuration information by a graph structure and the feature value of the element; and
for the design path information to be a target for learning by a learning model to be machine-learned so as to convert the abstract element into the concrete element using the concretization rule, generate design path information with distributed representation by calculating the distributed representation of the element in the system configuration information included by the design path information using the parameter and then assigning the distributed representation to the design path information.

2. The information processing apparatus according to claim 1, wherein the at least one processor is configured to execute the processing instructions to
generate property information representing a characteristic of the element as the feature value.

3. The information processing apparatus according to claim 1, wherein the at least one processor is configured to execute the processing instructions to
generate type information representing a type of the element as the feature value.

4. The information processing apparatus according to claim 1, wherein the at least one processor is configured to execute the processing instructions to
generate property information representing a characteristic of the element and type information representing a type of the element as the feature value.

5. The information processing apparatus according to claim 4, wherein the at least one processor is configured to execute the processing instructions to
express the property information by an array indicating presence or absence of the characteristic of the element and also express the type information by an array indicating presence or absence of the type of the element, and connect the array of the property information and the array of the type information to generate as the feature value.

6. The information processing apparatus according to claim 1, wherein the at least one processor is configured to execute the processing instructions to
when the feature value is associated with the element in the graph structure information and is input, acquire the parameter using a model that outputs the graph structure of the element accompanied by calculation of the distributed representation of the element.

7. The information processing apparatus according to claim 6, wherein the at least one processor is configured to execute the processing instructions to
when the feature value is associated with the element in the graph structure information and is input, acquire the parameter by learning, using a preset correct value of an output, a model that outputs a predicted value of the graph structure of the element accompanied by calculation of the distributed representation of the element.

8. The information processing apparatus according to claim 1, wherein the at least one processor is configured to execute the processing instructions to:
for each of the system configuration information included by the design path information with distributed representation, set a reward for the system configuration information based on whether or not the element included by the system configuration information is a concrete element; and
generate each of the system configuration information included by the design path information with distributed representation and the reward set for the system configuration information, as learning data to be machine-learned for generating a learning model that converts the system configuration information based on the concretization rule.

9. An information processing method by an information processing apparatus, the information processing method comprising:
collecting system configuration information included by design path information representing a process of designing the system configuration information, the system configuration information representing a system configuration including a combination of elements designed by converting an abstract element into a concrete element using a preset concretization rule;
generating a feature value of the element in the system configuration information included by the design path information;
acquiring, by machine learning, a parameter for calculating a distributed representation of the element using graph structure information representing a relation between the elements in the system configuration information by a graph structure and the feature value of the element; and
for the design path information to be a target for learning by a learning model to be machine-learned so as to convert the abstract element into the concrete element using the concretization rule, generating design path information with distributed representation by calculating the distributed representation of the element in the system configuration information included by the design path information using the parameter and then assigning the distributed representation to the design path information.

10. A non-transitory computer-readable storage medium storing a program, the program comprising instructions for causing an information processing apparatus to execute processes to:
collect system configuration information included by design path information representing a process of designing the system configuration information, the system configuration information representing a system configuration including a combination of elements designed by converting an abstract element into a concrete element using a preset concretization rule;
generate a feature value of the element in the system configuration information included by the design path information;
acquire, by machine learning, a parameter for calculating a distributed representation of the element using graph structure information representing a relation between the elements in the system configuration information by a graph structure and the feature value of the element; and
for the design path information to be a target for learning by a learning model to be machine-learned so as to convert the abstract element into the concrete element using the concretization rule, generate design path information with distributed representation by calculating the distributed representation of the element in the system configuration information included by the design path information using the parameter and then assigning the distributed representation to the design path information.
